(19) United States
(12) Patent Application Publication
(10) Pub. No.: US 2016/0260779 A1
(43) Pub. Date: Sep. 8, 2016

(54) NON-VOLATILE RESISTIVE RANDOM ACCESS MEMORY DEVICE

(71) Applicant: Kabushiki Kaisha Toshiba, Minato-ku (JP)

(72) Inventors: Tomohito KAWASHIMA, Yokohama (JP); Shosuke FUJII, Kuwana (JP)

(73) Assignee: Kabushiki Kaisha Toshiba, Minato-ku (JP)

(21) Appl. No.: 14/750,192

(22) Filed: Jun. 25, 2015

Related U.S. Application Data
(60) Provisional application No. 62/129,369, filed on Mar. 6, 2015.

(51) Int. Cl. H01L 27/24; H01L 45/00

(52) U.S. Cl. CPC H01L 27/2481; H01L 45/08; H01L 45/1266; H01L 45/145

(57) ABSTRACT

According to one embodiment, a resistive random access memory device includes a first wiring extending in a first direction, a first ion source layer provided in a first portion on the first wiring and a first variable resistance layer provided on the first ion source layer. The resistive random access memory device also includes a second wiring, which is provided on the first variable resistance layer, faces the first portion, and extends in a second direction different from the first direction. The resistive random access memory device also includes a second variable resistance layer provided in a second portion on the second wiring, a second ion source layer provided on the second variable resistance layer and a third wiring, which is provided on the second ion source layer, faces the second portion, and extends in the first direction.

### CROSS-REFERENCE TO RELATED APPLICATIONS

This application is based upon and claims the benefit of priority from U.S. Provisional Patent Application 62/129,369, filed on Mar. 6, 2015; the entire contents of which are incorporated herein by reference.

### FIELD

Embodiments described herein relate generally to a non-volatile resistive random access memory device.

### BACKGROUND

A two-terminal memory cell typified by an ReRAM (resistive random access memory) enables low-voltage operation, high-speed switching, and miniaturization. As a large-capacity memory device using this two-terminal memory cell, a cross-point type non-volatile resistive random access memory device has been proposed. In this cross-point type non-volatile resistive random access memory device, it is desired to suppress current leakage in a variable resistance layer.

### BRIEF DESCRIPTION OF THE DRAWINGS

FIG. 1 is a block diagram illustrating the non-volatile resistive random access memory device according to an embodiment;

FIG. 2 is a perspective view illustrating the non-volatile resistive random access memory device according to the embodiment;

FIG. 3 is a cross-sectional view taken along the line A-A′ shown in FIG. 2;

FIG. 4 is a cross-sectional view illustrating a region B shown in FIG. 3;

FIGS. 5A and 5B are cross-sectional views illustrating a region C1 shown in FIG. 4;

FIGS. 6A and 6B are timing charts illustrating a change in voltage applied to the memory cells of the non-volatile resistive random access memory device according to the embodiment, wherein the abscissa represents the time, and the ordinate represents the voltage;

FIG. 7 is a cross-sectional view illustrating a non-volatile resistive random access memory device according to the comparative example; and

FIGS. 8A and 8B are cross-sectional views illustrating a region C2 shown in FIG. 7.

### DETAILED DESCRIPTION

According to one embodiment, a resistive random access memory device includes a first wiring extending in a first direction, a first ion source layer provided in a first portion on the first wiring and a first variable resistance layer provided on the first ion source layer. The resistive random access memory device also includes a second wiring, which is provided on the first variable resistance layer, faces the first portion, and extends in a second direction different from the first direction. The resistive random access memory device also includes a second variable resistance layer provided in a second portion on the second wiring, a second ion source layer provided on the second variable resistance layer and a third wiring, which is provided on the second ion source layer, faces the second portion, and extends in the first direction. The first ion source layer being formed from a material different from that of the second ion source layer.

Hereinafter, an embodiment of the invention will be described with reference to the drawings.

### EMBODIMENT

A configuration of a non-volatile resistive random access memory device 1 according to the embodiment will be described.

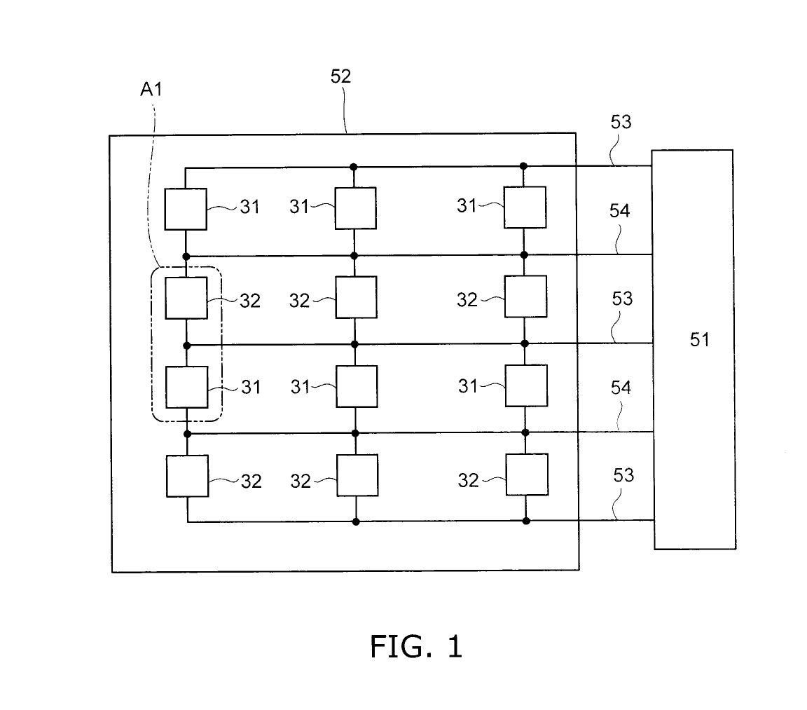

FIG. 1 is a block diagram illustrating the non-volatile resistive random access memory device according to the embodiment.

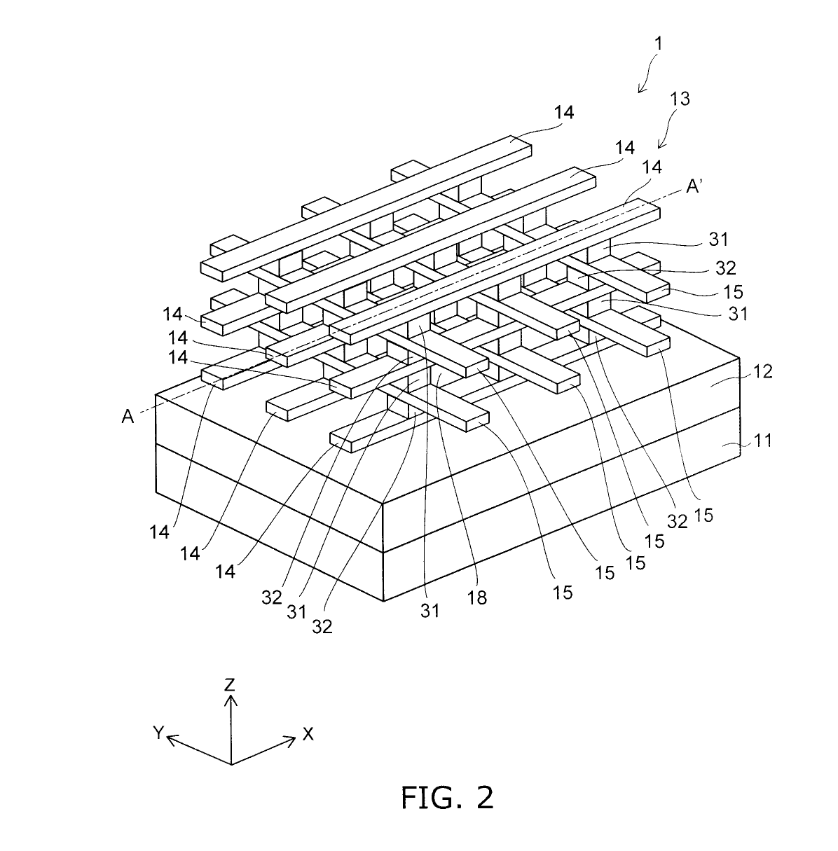

As shown in FIG. 1, the non-volatile resistive random access memory device 1 is provided with a driving circuit 51, a cell array 52, a control bus 53, and a data bus 54. In the cell array 52, multiple memory cells are provided. In the memory cells, there are two types of memory cells: a memory cell 31 and a memory cell 32. The driving circuit 51 and each memory cell 31 are connected through the control bus 53 and the data bus 54. In the same manner, the driving circuit 51 and each memory cell 32 are connected through the control bus 53 and the data bus 54. The control bus 53 is shared by the memory cell 32 and the memory cell 31 adjacent to each other, and the data bus 54 is shared by the memory cell 31 and the memory cell 32 adjacent to each other. Incidentally, the memory cells 31 and 32 in a portion Al in FIG. 1 are a pair of memory cells which are adjacent to each other through a wiring 14 shown in FIG. 2.

FIG. 2 is a perspective view illustrating the non-volatile resistive random access memory device according to the embodiment.

As shown in FIG. 2, the non-volatile resistive random access memory device 1 according to the embodiment is provided with a substrate 11. The substrate 11 is provided with the driving circuit (not shown) of the non-volatile resistive random access memory device. On the substrate 11, an insulating film 12 is provided. On the insulating film 12, a stacked body 13 is provided.

Hereinafter, in the specification, an XYZ orthogonal coordinate system is adopted for the sake of convenience of explanation.

That is, in FIG. 2, two directions parallel to the contact surface between the substrate 11 and the insulating film 12 and orthogonal to each other are defined as “X-direction” and “Y-direction”. Further, a direction in which the stacked body 13 is provided with respect to the contact surface between the substrate 11 and the insulating film 12 is defined as “Z-direction”.

In the stacked body 13, multiple wirings (electrodes) 14 separated in the Y-direction and extending in the X-direction, and multiple wirings (electrodes) 15 separated in the X-direction and extending in the Y-direction are alternately stacked. The wirings 14 are not connected to one another, and also the wirings 15 are not connected to one another. Further, the wirings 14 and the wirings 15 are mutually not connected to each other.

A memory cell extending in the Z-direction is provided in each portion which is located between each of the wirings 14 and each of the wirings 15 and is a portion where the wiring 14 and the wiring 15 cross each other. In portions other than the wirings 14, the wirings 15, and the memory cells, insulating members 18 are provided.

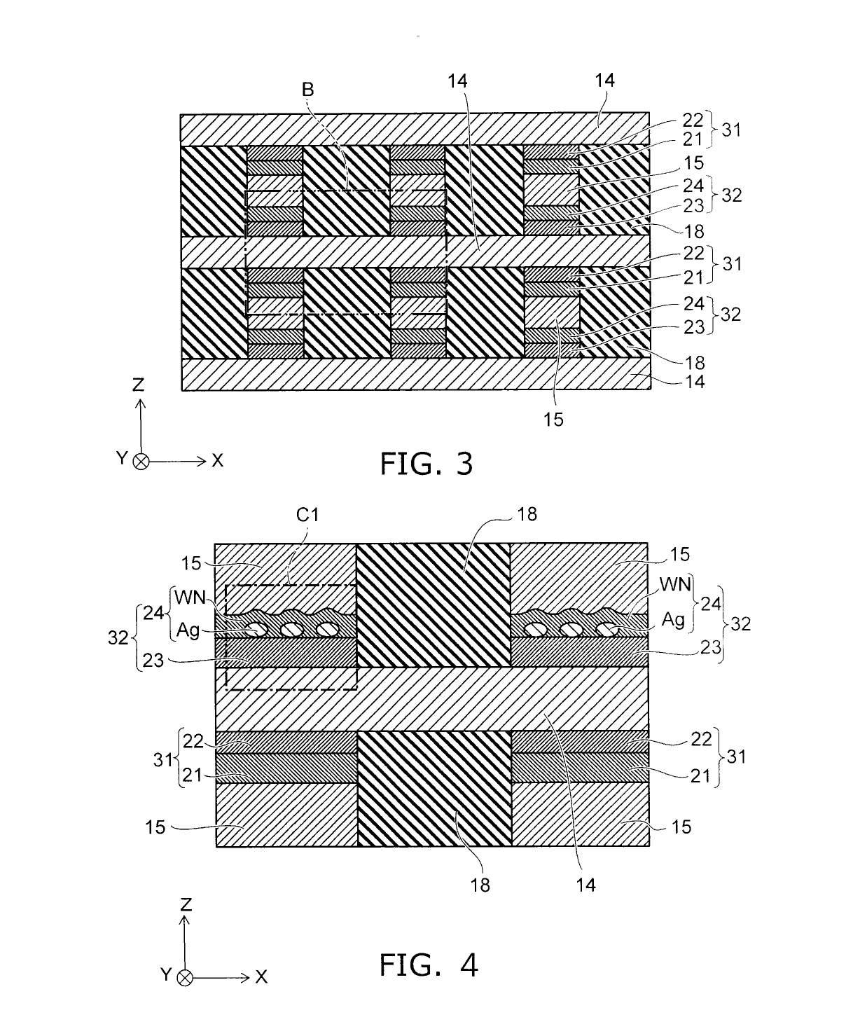

FIG. 3 is a cross-sectional view taken along the line A-A′ shown in FIG. 2.

FIG. 4 is a cross-sectional view illustrating a region B shown in FIG. 3.

As shown in FIGS. 3 and 4, in the memory cell 32, a variable resistance layer 23 is provided on the wiring 14, and an ion source layer 24 is provided on the variable resistance layer 23. A structure in which the ion source layer 24 is provided on the variable resistance layer 23 is called “stacking structure in first order”. In the memory cell 31, an ion source layer 21 is provided on the wiring 15, and a variable resistance layer 22 is provided on the ion source layer 21. A structure in which the variable resistance layer 22 is provided on the ion source layer 21 is called “stacking structure in second order”.

The variable resistance layer 22 and the variable resistance layer 23 are disposed at positions facing each other by interposing the wiring 14. Further, also the ion source layer 21 and the ion source layer 24 are disposed at positions facing each other by interposing the wiring 14. According to this configuration, the wiring 14 can be shared by the memory cell 31 and the memory cell 32. That is, as the wirings of the memory cell 32, the wiring 14 and the wiring 15 in contact with the ion source layer 24 can be used. Further, as the wirings of the memory cell 31, the wiring 14 and the wiring 15 in contact with the ion source layer 21 can be used

The variable resistance layer 23 is formed from, for example, silicon oxide (SiO₂).

The ion source layer 24 is formed from an ion source for supplying ions to the variable resistance layer 23 and a barrier metal for preventing diffusion of a metal material of the wiring 15.

The ion source of the ion source layer 24 is formed from a material which is less likely to reduce silicon oxide in the variable resistance layer 23, for example, silver (Ag).

In the same manner as the ion source, the barrier metal of the ion source layer 24 is formed from a material which is less likely to reduce silicon oxide in the variable resistance layer 23. Examples of the material of the barrier metal of the ion source layer 24 include titanium nitride (TiN), tantalum nitride (TaN), and tungsten nitride (WN). Among these, tungsten nitride is preferred.

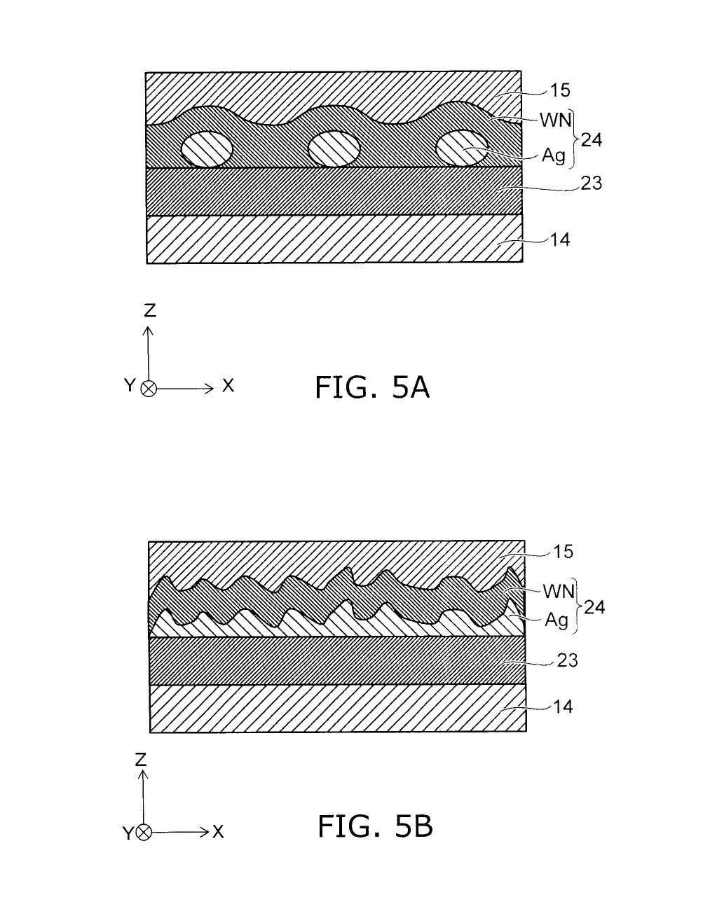

FIGS. 5A and 5B are cross-sectional views illustrating a region C1 shown in FIG. 4. As shown in FIGS. 4 and 5A, in the case where the ion source layer 24 is formed from silver and tungsten nitride, silver aggregates on the foundation side of the ion source layer 24. This is because silver has a high surface tension. When silver aggregates, a portion, in which silver aggregates, in the ion source layer 24 swells, and many convex portions are formed on the contact surface between the ion source layer 24 and the wiring 15. The contact surface between the variable resistance layer 23 and the ion source layer 24 is smooth, and the thickness of the variable resistance layer 23 does not change.

Incidentally, the manner of aggregation of silver is not limited to the case where the respective aggregates of silver are not connected to one another (see FIG. 5A). For example, as shown in FIG. 5B, there may also be a case where the aggregation of silver occurs in a continuous manner on the foundation side of the ion source layer 24, and the respective aggregates of silver are connected to one another.

The ion source of the ion source layer 21 of the memory cell 31 in which the stacking structure is a stacking structure in second order is formed from a material different from that of the ion source of the ion source layer 24 of the memory cell 32 in which the stacking structure is a stacking structure in first order. The ion source of the ion source layer 21 is formed from a material which is less likely to aggregate, for example, titanium (Ti). Silver has a high surface tension and is likely to aggregate, and therefore, as the material of the ion source of the ion source layer 21, titanium is preferred to silver.

The variable resistance layer 22 of the memory cell 31 in which the stacking structure is a stacking structure in second order is formed from a material different from that of the variable resistance layer 23 of the memory cell 32 in which the stacking structure is a stacking structure in first order. Further, there may be a case where in the variable resistance layer 22, the material of the variable resistance layer 22 reacts with the material of the ion source of the ion source layer 21 so that the material of the ion source is changed. For example, in the case where silicon oxide is used as the material of the variable resistance layer 22 and titanium is used as the material of the ion source, titanium takes oxygen from silicon oxide and is converted into titanium oxide (TiO₂). Therefore, the variable resistance layer 22 is formed from a material which is less likely to react with titanium of the ion source layer 21, for example, hafnium oxide (HfO₂).

The variable resistance layer 23 may be formed from, for example, silicon (Si), aluminum oxide (Al₂O₃), hafnium oxide (HfO₂), niobium oxide (Nb₂O₅), zirconium oxide (Zr₂O₃), vanadium oxide (V₂O₅), or molybdenum oxide (MoO₃) other than silicon oxide (SiO₂).

The ion source of the ion source layer 24 may be formed from any material as long as the material is less likely to reduce the oxide in the variable resistance layer 23, and the material may be, for example, copper (Cu), gold (Au), aluminum (Al), iron (Fe), manganese (Mn), cobalt (Co), nickel (Ni), or zinc (Zn) other than silver (Ag).

The ion source of the ion source layer 21 may be formed from any material as long as the material is less likely to aggregate, and the material may be, for example, tantalum (Ta), titanium nitride (TiN), tantalum nitride (TaN), tungsten nitride (WN), zirconium nitride (ZrN), or titanium tungsten (TiW) other than titanium (Ti).

The variable resistance layer 22 may be formed from, for example, silicon (Si), aluminum oxide (Al₂O₃), niobium oxide (Nb₂O₅), zirconium oxide (Zr₂O₃), vanadium oxide (V₂O₅), or molybdenum oxide (MoO₃) other than hafnium oxide (HfO₂).

Incidentally, in the drawings, the ion source layer 21 does not have a barrier metal, but may have a barrier metal such as titanium nitride (TiN), tantalum nitride (TaN), or tungsten nitride (WN). In such a case, the barrier metal is located on the wiring 15 side, and the ion source may be disposed so as to be located in the variable resistance layer 22.

As a representative combination for the memory cell 32 in which the stacking structure is a stacking structure in first order, for example, the variable resistance layer 23 has silicon oxide, and the ion source layer 24 has silver or copper. As a representative combination for the memory cell 31 in which the stacking structure is a stacking structure in second order, for example, the variable resistance layer 22 has hafnium oxide, and the ion source layer 21 has titanium. In this manner, the memory cell 32 having a stacking structure in first order and the memory cell 31 having a stacking structure in second order are formed from different materials.

Further, the thickness of the variable resistance layer 23 and the thickness of the variable resistance layer 22 may be different. In FIG. 4, the thickness of the variable resistance layer 22 is thinner than that of the variable resistance layer 23.

Next, an operation of the non-volatile resistive random access memory device 1 according to the embodiment will be described.

As shown in FIG. 1, write-in, read-out, verify, etc. for memory cells 31 and 32 are carried out through the control bus 53 and the data bus 54. By changing a voltage to be applied to the memory cells 31 and 32 through the control bus 53, write-in, read-out, verify, etc. are carried out.

Write-in is an operation of storing data in the memory cells. Verify is an operation of verifying whether or not the data written in the memory cells are correct. Hereinafter, a description will be made by illustrating the write-in and verify operations.

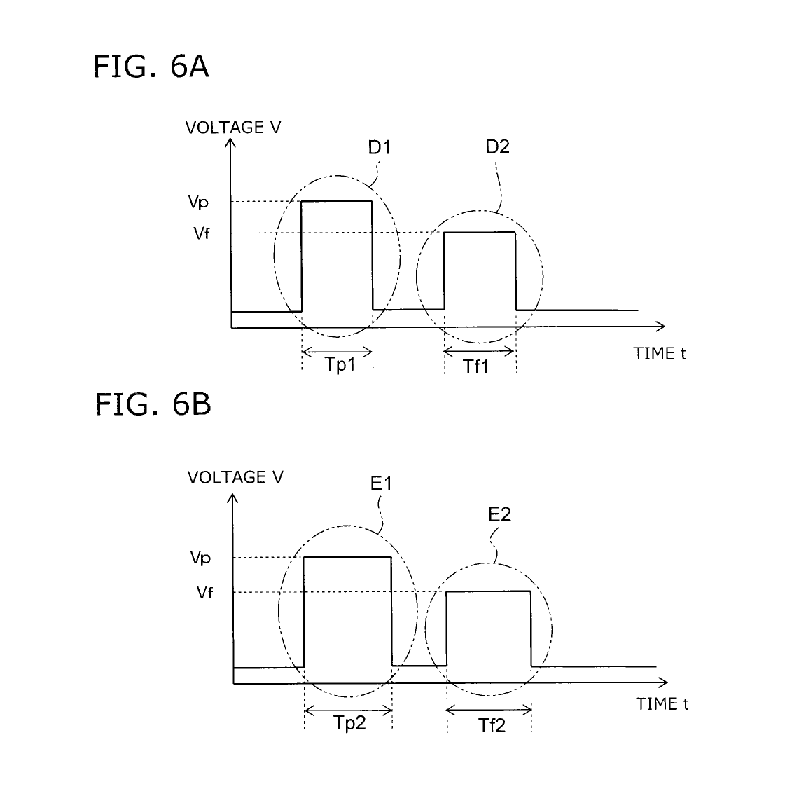

FIGS. 6A and 6B are timing charts illustrating a change in voltage applied to the memory cells 32 and 31, wherein the abscissa represents the time, and the ordinate represents the voltage. A pulse D1 shown in FIG. 6A illustrates a write-in operation for the memory cell 32, and a pulse D2 shown in FIG. 6A illustrates a verify operation for the memory cell 32. A pulse E1 shown in FIG. 6B illustrates a write-in operation for the memory cell 31, and a pulse E2 shown in FIG. 6B illustrates a verify operation for the memory cell 31.

As shown by the pulse D1 in FIG. 6A, a write-in operation is carried out by applying a voltage Vp to the memory cell 32 during a period of Tp1 to bring the variable resistance layer 23 shown in FIG. 3 from a high-resistance state to a low-resistance state. For example, this high-resistance state is made to correspond to data “0”, and the low-resistance state is made to correspond to data “1”. The voltage Vp corresponds to a voltage between the wiring 14 and the wiring 15 shown in FIG. 3, and the potential of the wiring 15 is higher than that of the wiring 14.

As shown by the pulse D2 in FIG. 6A, the state of the variable resistance layer 23 is read-out by applying a voltage Vf to the memory cell 32 during a period of Tf1 and measuring the current of the variable resistance layer 23 shown in FIG. 3. That is, a verify operation is carried out as follows: in the case where the current is higher than a threshold value, the variable resistance layer 23 is determined to be in a low-resistance state (PASS), and in the case where the current is not higher than the threshold value, the variable resistance layer 23 is determined to be in a high-resistance state (FAIL). The voltage Vf corresponds to a voltage between the wiring 14 and the wiring 15 shown in FIG. 3, and the potential of the wiring 15 is higher than that of the wiring 14.

Incidentally, in the case where the verify result becomes “FAIL”, a loop of write-in and verify operations is carried out again. At this time, the voltage Vp may be increased by a given voltage. The loop of write-in and verify operations is repeated until the verify result becomes “PASS”.

In the embodiment, the configuration of the ion source layer is different between the memory cell 31 and the memory cell 32. Therefore, the pulse of a write-in voltage to be applied to the memory cell 32 and the pulse of a write-in voltage to be applied to the memory cell 31 are different in shape. In the driving circuit 51, electrical circuits for generating the pulse of a write-in voltage to be applied to the memory cells 32 and 31 are needed, respectively. Due to this, it is desired that the write-in voltages Vp to be applied to the memory cells 32 and 31 are standardized to one value of voltage.

Accordingly, the thickness of the variable resistance layer 23 and the thickness of the variable resistance layer 22 are set, respectively, so that the write-in voltage to be applied to the memory cell 32 and the write-in voltage to be applied to the memory cell 31 become the same value.

By doing this, the variable resistance layer 23 has a thickness different from that of the variable resistance layer 22.

For example, in the case where the write-in operation for the memory cell 31 is more difficult than for the memory cell 32 by forming the variable resistance layer 22 from hafnium oxide (HfO₂) and by forming the variable resistance layer 23 from silicon oxide (SiO₂), or the like, the thickness of the variable resistance layer 22 is thinner than that of the variable resistance layer 23.

As a result, as shown in the pulse E1 in FIG. 6B, the write-in voltage Vp to be applied to the memory cell 31 can be made substantially the same value as the write-in voltage Vp to be applied to the memory cell 32. Incidentally, the thicknesses of the variable resistance layers 23 and 22 may be set, respectively, so that the verify voltages to be applied to the memory cells 32 and 31 become the same voltage. In this case, as shown in the pulse E2 in FIG. 6B, the verify voltage Vf to be applied to the memory cell 31 can be made substantially the same value as the verify voltage Vf to be applied to the memory cell 32.

Incidentally, the application times for the pulse D1 and the pulse E1 may be adjusted so that the write-in voltages to be applied to the memory cells 32 and 31 are substantially the same value of voltage. In this case, the application time Tp1 for the pulse D1 and the application time Tp2 for the pulse E1 are different values. In the same manner, the application times for the pulse D2 and the pulse E2 may be adjusted in such a manner that the application time Tf1 for the pulse D2 and the application time Tf2 for the pulse E2 are set to different values so that the verify voltages to be applied to the memory cells 32 and 31 are substantially the same voltage. For example, in the case where the write-in operation for the memory cell 31 is more difficult than for the memory cell 32, the application time Tp2 for the pulse E1 may be set longer than the application time Tp1 for the pulse D1, and the application time Tf2 for the pulse E2 may be set longer than the application time Tf1 for the pulse D2. Further, accompanying this, the time for one loop of write-in and verify operations for the memory cell 31 may be set longer than the time for one loop of write-in and verify operations for the memory cell 32. Alternatively, the time between each pulse for the memory cell 32 is set long, and the times for one loop of write-in and verify operations for the memory cells 31 and 32 may be set to the same time. The former can reduce the time for the write-in operation in the non-volatile memory device, and the latter can simplify the control during the write-in operation.

The effect of the non-volatile resistive random access memory device 1 according to the embodiment will be described.

In the non-volatile resistive random access memory device 1 according to the embodiment, as the material of the ion source of the ion source layer 21, a material which has a low surface tension and is less likely to aggregate is used. Examples of the material which has a low surface tension and is less likely to aggregate include titanium (Ti). In the case where aggregation does not occur, the thickness of the variable resistance layer 22 hardly changes.

In the case where the material of the ion source aggregates in the ion source layer 21, and convexo-concave are formed on the surface of the ion source layer 21, a portion in which the thickness of the variable resistance layer 22 is locally thin is formed. Due to this, when a voltage of less than the voltage Vp is applied to the memory cell 31, current leakage occurs in the variable resistance layer 22, and the variable resistance layer 22 cannot be switched between a high-resistance state and a low-resistance state. Therefore, by using a material which is less likely to aggregate as the material of the ion source of the ion source layer 22, an ion source layer with few convexo-concave is formed, thereby suppressing current leakage.

As a result, a non-volatile resistive random access memory device in which current leakage is suppressed can be provided.

### COMPARATIVE EXAMPLE

Next, a comparative example will be described.

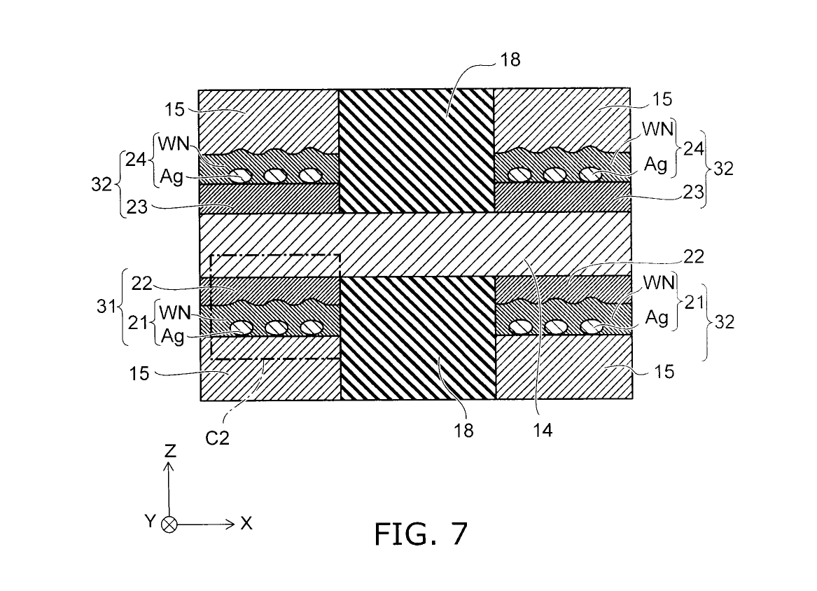

FIG. 7 is a cross-sectional view illustrating a non-volatile resistive random access memory device according to the comparative example.

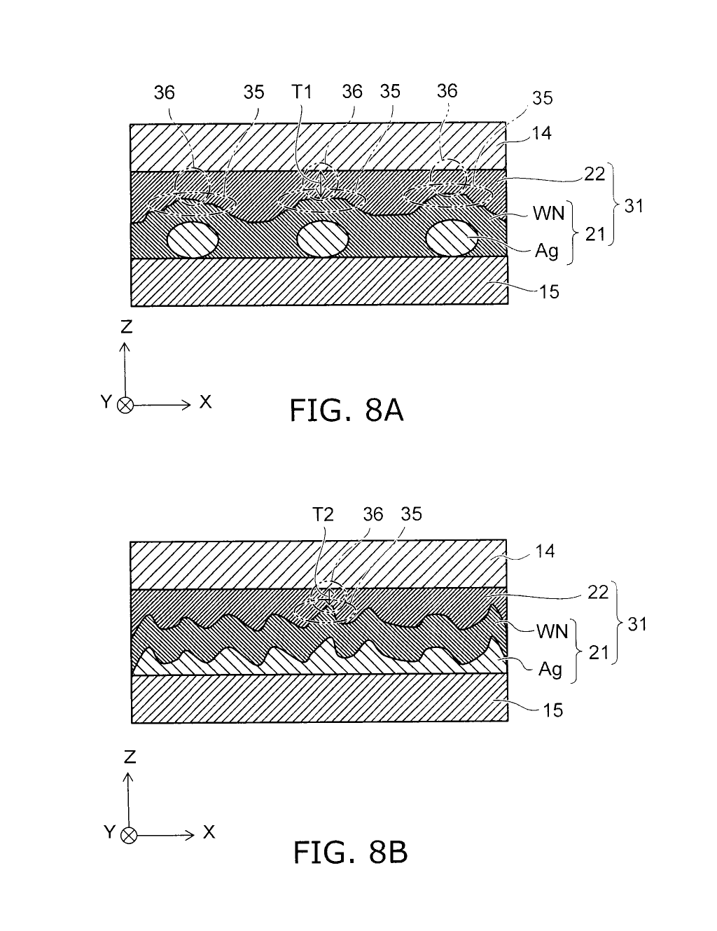

FIGS. 8A and 8B are cross-sectional views illustrating a region C2 shown in FIG. 7. As shown in FIGS. 7 and 8A, in the case where the ion source layer 21 is formed from silver and tungsten nitride in the same manner as the ion source layer 24, silver aggregates on the foundation side of the ion source layer 21. This is because silver has a high surface tension.

When silver aggregates, a portion 35, in which silver aggregates, in the ion source layer 21 swells, and many convex portions are formed on the contact surface between the ion source layer 21 and the variable resistance layer 22. The thickness T1 of a portion 36 in the variable resistance layer 22 corresponding to the portion 35 becomes thinner as compared with the case where silver does not aggregate. Due to the formation of the portion 36 having a thin thickness in the variable resistance layer 22, when a voltage of less than the voltage Vp is applied to the memory cell 31, the variable resistance layer 22 is changed, for example, from a high-resistance state to a low-resistance state, and a leakage current may flow in some cases.

Incidentally, as shown in FIG. 8B, there may also be a case where the aggregation of silver in the ion source layer 21 occurs in a continuous manner on the foundation side of the ion source layer 21 in the same manner as the aggregation of silver in the ion source layer 24 in the above-described embodiment (see FIG. 5B), and the respective aggregates of silver are connected to one another. Also in this case, the thickness T2 of a portion 36 in the variable resistance layer 22 corresponding to a portion 35 in which silver aggregates becomes thinner as compared with the case where silver does not aggregate.

According to the embodiment described above, a non-volatile resistive random access memory device in which current leakage is suppressed can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A resistive random access memory device, comprising:
a first wiring extending in a first direction;
a first ion source layer provided in a first portion on the first wiring;
a first variable resistance layer provided on the first ion source layer;
a second wiring, which is provided on the first variable resistance layer, faces the first portion, and extends in a second direction different from the first direction;
a second variable resistance layer provided in a second portion on the second wiring;
a second ion source layer provided on the second variable resistance layer; and
a third wiring, which is provided on the second ion source layer, faces the second portion, and extends in the first direction,
the first ion source layer being formed from a material different from that of the second ion source layer.

2. The device according to claim 1, wherein
the first variable resistance layer is formed from a material different from that of the second variable resistance layer.

3. The device according to claim 1, wherein
the second ion source layer contains silver, copper, gold, aluminum, iron, manganese, cobalt, nickel, or zinc, and
the second variable resistance layer contains silicon oxide, silicon, aluminum oxide, hafnium oxide, niobium oxide, zirconium oxide, vanadium oxide, or molybdenum oxide.

4. The device according to claim 1, wherein
the first variable resistance layer contains hafnium oxide, silicon, aluminum oxide, niobium oxide, zirconium oxide, vanadium oxide, or molybdenum oxide, and
the first ion source layer contains titanium, tantalum, titanium nitride, tantalum nitride, tungsten nitride, zirconium nitride, or titanium tungsten.

5. The device according to claim 1, wherein
the second variable resistance layer has a thickness different from that of the first variable resistance layer.

6. The device according to claim 1, wherein
the first variable resistance layer has a thickness thinner than that of the second variable resistance layer.

7. The device according to claim 1, wherein
the second variable resistance layer is disposed immediately above the first variable resistance layer.

8. The device according to claim 1, wherein
a write-in pulse to be applied to the first variable resistance layer and a write-in pulse to be applied to the second variable resistance layer are different in shape.

9. The device according to claim 1, wherein
an application time for a write-in pulse to be applied to the first variable resistance layer is different from an application time for a write-in pulse to be applied to the second variable resistance layer.

10. The device according to claim 1, wherein
an application time for a write-in pulse to be applied to the first variable resistance layer is longer than an application time for a write-in pulse to be applied to the second variable resistance layer.

11. The device according to claim 1, wherein
a verify pulse to be applied to the first variable resistance layer and a verify pulse to be applied to the second variable resistance layer are different in shape.

12. The device according to claim 1, wherein
an application time for a verify pulse to be applied to the first variable resistance layer is different from an application time for a verify pulse to be applied to the second variable resistance layer.

13. The device according to claim 1, wherein
an application time for a verify pulse to be applied to the first variable resistance layer is longer than an application time for a verify pulse to be applied to the second variable resistance layer.

14. A resistive random access memory device, comprising:
a first wiring extending in a first direction;
a first ion source layer, which is provided in a first portion on the first wiring, and has a first ion source;
a first variable resistance layer provided on the first ion source layer;
a second wiring, which is provided on the first variable resistance layer, faces the first portion, and extends in a second direction different from the first direction;
a second variable resistance layer provided in a second portion on the second wiring;
a second ion source layer, which is provided on the second variable resistance layer, and has a second ion source and a second barrier metal; and
a third wiring, which is provided on the second ion source layer, faces the second portion, and extends in the first direction,
the second ion source layer having an upper surface which is rougher as compared with the first ion source layer.

15. The device according to claim 14, wherein
the first variable resistance layer has a thickness different from that of the second variable resistance layer.

16. The device according to claim 14, wherein
the first variable resistance layer has a thickness thinner than that of the second variable resistance layer.

17. The device according to claim 14, wherein
the second variable resistance layer is disposed immediately above the first variable resistance layer.

18. The device according to claim 14, wherein
an application time for a write-in pulse to be applied to the first variable resistance layer is longer than an application time for a write-in pulse to be applied to the second variable resistance layer.

19. The device according to claim 14, wherein
an application time for a write-in pulse to be applied to the first variable resistance layer is longer than an application time for a write-in pulse to be applied to the second variable resistance layer, and the first variable resistance layer has a thickness thinner than that of the second variable resistance layer.

20. The device according to claim 14, wherein
the second ion source aggregates more than the first ion source.
